(19) United States
(12) Patent Application Publication
(10) Pub. No.: US 2025/0140953 A1
(43) Pub. Date: May 1, 2025

(54) BATTERY PACK AND CURRENT SENSOR DIAGNOSIS METHOD

(71) Applicant: SAMSUNG SDI CO., LTD., Yongin-si (KR)

(72) Inventor: Pyung Kap KIM, Suwon-si (KR)

(21) Appl. No.: 18/415,248

(22) Filed: Jan. 17, 2024

(30) Foreign Application Priority Data
Oct. 31, 2023 (KR) 10-2023-0148107

(51) Int. Cl. H01M 10/48; G01R 31/382; G01R 31/392; H01M 10/42

(52) U.S. Cl. CPC H01M 10/482; G01R 31/382; G01R 31/392; H01M 10/4207

(57) ABSTRACT

A battery pack and a current sensor diagnosis method that enable diagnosis of abnormality of a current sensor including a shunt resistor, the battery pack including a battery module including battery cells, a current sensor for measuring a current in the battery module, a first switch connected to a first current path between a cathode of the battery module and a first pack terminal, a second switch connected to a second current path between an anode of the battery module and a second pack terminal, a first temperature sensor for measuring a shunt temperature of the current sensor, a second temperature sensor for measuring a first switch temperature, a third temperature sensor for measuring a second switch temperature, and a processor for diagnosing the current sensor based on at least one of the shunt temperature, the first switch temperature, or the second switch temperature.

### CROSS-REFERENCE TO RELATED APPLICATION

The present application claims priority to and the benefit of Korean Patent Application No. 10-2023-0148107, filed on Oct. 31, 2023, in the Korean Intellectual Property Office, the entire disclosure of which is incorporated herein by reference.

### BACKGROUND

### 1. Field

The present disclosure relates to a battery pack and a diagnosis method for diagnosing an abnormality.

### 2. Description of the Related Art

With rapidly increasing desire for portable electronic products, such as laptops, video cameras, and mobile phones, and for the development of electric vehicles, energy storage batteries, robots, satellites, and the like, active research has been carried out on development of high-performance secondary batteries (hereafter referred to as batteries) that can be repeatedly charged and discharged.

In general, a power supply system of a battery may be provided with a current sensor to measure current. The current sensor measures the current flowing along a charge/discharge path of the battery to monitor the state of the battery, to detect overcurrent in the battery, and the like. The current measured by the current sensor can be used as information to calculate the SOC (state of charge) of the battery, or can be used as a basis for determining whether a charging/discharging process is normally carried out, and the like.

A shunt resistor may be used as a component for measurement of a current flowing through a battery, and the current may be measured by measuring a voltage across the shunt resistor. However, if the shunt resistor does not operate normally, the current flowing through the battery cannot be measured properly. As a result, even in the event of an abnormal situation, such as overcurrent and the like, the shunt resistor cannot block the overcurrent properly, thereby causing serious problems, such as battery failure or explosion.

This section is intended only to provide a better understanding of the background of the present disclosure, and thus may include information which is not necessarily prior art.

### SUMMARY

An aspect of the present disclosure provides a battery pack and a current sensor diagnosis method that enables diagnosis of an abnormality of a current sensor including a shunt resistor.

The above and other aspects of the present disclosure will become apparent from the following description of embodiments of the present disclosure.

According to one or more embodiments, a battery pack includes a battery module including battery cells, a current sensor for measuring a current in the battery module, a first switch connected to a first current path between a cathode of the battery module and a first pack terminal, a second switch connected to a second current path between an anode of the battery module and a second pack terminal, a first temperature sensor for measuring a shunt temperature of the current sensor, a second temperature sensor for measuring a first switch temperature of the first switch, a third temperature sensor for measuring a second switch temperature of the second switch, and a processor for diagnosing the current sensor based on at least one of the shunt temperature, the first switch temperature, or the second switch temperature.

The current sensor may include a shunt resistor, wherein the shunt temperature is indicative of a temperature of the shunt resistor.

The processor may be configured to diagnose an abnormality of the current sensor by comparing at least one of the shunt temperature, the first switch temperature, or the second switch temperature with at least one of a shunt maximum temperature, a first switch maximum temperature, or a second switch maximum temperature.

The processor may be configured to determine that the current sensor is normal when the shunt temperature is less than or equal to the shunt maximum temperature, the first switch temperature is less than or equal to the first switch maximum temperature, and the second switch temperature is less than or equal to the second switch maximum temperature.

The processor may be configured to determine that the current sensor is abnormal when the shunt temperature exceeds the shunt maximum temperature, the first switch temperature is less than or equal to the first switch maximum temperature, and the second switch temperature is less than or equal to the second switch maximum temperature.

Upon determining that the current sensor is abnormal, the processor may be configured to calculate an average temperature of the shunt temperature, the first switch temperature, and the second switch temperature, and is configured to compare the average temperature with the shunt temperature, the first switch temperature, and the second switch temperature to determine a type of the abnormality of the current sensor.

The processor may be configured to determine that a shunt-resistance-value-decrease failure has occurred when a difference between the shunt temperature and the average temperature is negative, a difference between the first switch temperature and the average temperature is positive, and a difference between the second switch temperature and the average temperature is positive.

The processor may be configured to determine that a shunt-resistance-value-increase failure has occurred when a difference between the shunt temperature and the average temperature is positive, a difference between the first switch temperature and the average temperature is negative, and a difference between the second switch temperature and the average temperature is negative.

The battery pack may further include a lookup table for setting therein at least one of a shunt saturation temperature, a first switch saturation temperature, or a second switch saturation temperature depending on current, wherein the processor is configured to calculate an average of current accumulated, obtain the shunt saturation temperature, the first switch saturation temperature, and the second switch saturation temperature corresponding to the average of the current accumulated from the lookup table, calculate a shunt temperature difference meaning an absolute value of a difference between the shunt temperature and the shunt saturation temperature, a first switch temperature difference meaning an absolute value of a difference between the first switch temperature and the first switch saturation temperature, and a second switch temperature difference meaning an absolute value of a difference between the second switch temperature and the second switch saturation temperature, and compare the shunt temperature difference, the first switch temperature difference, and the second switch temperature difference with a reference value to diagnose an abnormality of the current sensor.

The processor may be configured to determine that the current sensor is normal when the shunt temperature difference is less than or equal to the reference value, the first switch temperature difference is less than or equal to the reference value, and the second switch temperature difference is less than or equal to the reference value.

The processor may be configured to determine that the current sensor is abnormal when the shunt temperature difference exceeds the reference value, the first switch temperature difference is less than or equal to the reference value, and the second switch temperature difference is less than or equal to the reference value.

Upon determining that the current sensor is abnormal, the processor may be configured to determine a type of the abnormality of the current sensor based on a sign of the difference between the shunt temperature and the shunt saturation temperature.

The processor may be configured to determine that a shunt-resistance-value-decrease failure has occurred when the difference between the shunt temperature and the shunt saturation temperature is negative, and to determine that a shunt-resistance-value-increase failure has occurred when the difference between the shunt temperature and the shunt saturation temperature is positive.

According to one or more embodiments a current sensor diagnosis method includes calculating, by a processor, an average of current accumulated, obtaining, by the processor, a shunt saturation temperature, a first switch saturation temperature, and a second switch saturation temperature corresponding to the average of the current accumulated, calculating, by the processor, a shunt temperature difference meaning an absolute value of a difference between a shunt temperature measured by a first temperature sensor and the shunt saturation temperature, a first switch temperature difference meaning an absolute value of a difference between a first switch temperature measured by a second temperature sensor and the first switch saturation temperature, and a second switch temperature difference meaning an absolute value of a difference between a second switch temperature measured by a third temperature sensor and the second switch saturation temperature, and diagnosing, by the processor, an abnormality of a current sensor by comparing the shunt temperature difference, the first switch temperature difference, and the second switch temperature difference with a reference value.

Diagnosing the abnormality of the current sensor may include determining that the current sensor is normal when the shunt temperature difference is less than or equal to the reference value, the first switch temperature difference is less than or equal to the reference value, and the second switch temperature difference is less than or equal to the reference value.

Diagnosing the abnormality of the current sensor may include determining that the current sensor is abnormal when the shunt temperature difference exceeds the reference value, the first switch temperature difference is less than or equal to the the reference value.

The current sensor diagnosis method may further include determining that a shunt-resistance-value-decrease failure has occurred when the difference between the shunt temperature and the shunt saturation temperature is negative, and determining that a shunt-resistance-value-increase failure has occurred when the difference between the shunt temperature and the shunt saturation temperature is positive.

According to one or more embodiments, a current sensor diagnosis method includes receiving, by a processor, at least one of a shunt temperature measured by a first temperature sensor, a first switch temperature measured by a second temperature sensor, or a second switch temperature measured by a third temperature sensor, and diagnosing, by the processor, abnormality of a current sensor by comparing at least one of the shunt temperature, the first switch temperature, or the second switch temperature with at least one of a shunt maximum temperature, a first switch maximum temperature, or a second switch maximum temperature.

Diagnosing the abnormality of the current sensor may include determining that the current sensor is normal when a shunt temperature difference, meaning an absolute value of a difference between the shunt temperature and a shunt saturation temperature, is less than or equal to a reference value, a first switch temperature difference, an absolute value of a difference between the first switch temperature and a first switch saturation temperature, is less than or equal to the reference value, and a second switch temperature difference, meaning an absolute value of a difference between the second switch temperature and a second switch saturation temperature, is less than or equal to the reference value.

Diagnosing the abnormality of the current sensor may include determining that the current sensor is abnormal when the shunt temperature difference exceeds the reference value, the first switch temperature difference is less than or equal to the the reference value.

In accordance with an aspect of the present disclosure, a battery pack diagnoses a current sensor based on at least one of a shunt temperature measured at a shunt resistor, a first switch temperature measured at a first switch, or a second switch temperature measured at a second switch.

According to the present disclosure, the battery pack and the current sensor diagnosis method can detect abnormality (e.g., a failure or defect) of a shunt resistor, thereby enabling accurate detection of overcurrent through diagnosis of abnormality of a current sensor including a shunt resistor.

According to the present disclosure, the battery pack and the current sensor diagnosis method can reduce or prevent the likelihood of problems, such as battery failure and explosion due to abnormalities (e.g., errors or failure) of the shunt resistor.

According to the present disclosure, the battery pack and the current sensor diagnosis method can detect an abnormality (e.g., a failure or a defect) of the shunt resistor, and can reduce a risk caused by abnormality of the shunt resistor by changing abnormality of the shunt resistor from a single point fault to a dual point fault.

However, aspects of the present disclosure are not limited to the above, and other aspects not mentioned will be clearly understood by those skilled in the art from the detailed description given below.

### BRIEF DESCRIPTION OF THE DRAWINGS

The following drawings attached to this specification illustrate embodiments of the present disclosure, and further describe aspects of the present disclosure together with the detailed description of the present disclosure. Thus, the present disclosure should not be construed as being limited to the drawings:

FIG. 1 is a block diagram of a battery pack;

FIG. 2 is a circuit diagram of the battery pack;

FIG. 3 is a flowchart illustrating a current sensor diagnosis method according to one or more embodiments of the present disclosure; and

FIG. 4 is a flowchart illustrating a current sensor diagnosis method according to one or more other embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware, to process data or digital signals. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Circuit hardware may include, for example, application specific integrated circuits (ASICs), general purpose or special purpose central processing units (CPUs) that is configured to execute instructions stored in a non-transitory storage medium, digital signal processors (DSPs), graphics processing units (GPUs), and programmable logic devices such as field programmable gate arrays (FPGAs).

Further, the various components of these devices may be a process or thread, running on one or more processors, in one or more computing devices, executing computer program instructions and interacting with other system components for performing the various functionalities described herein. The computer program instructions are stored in a memory that may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

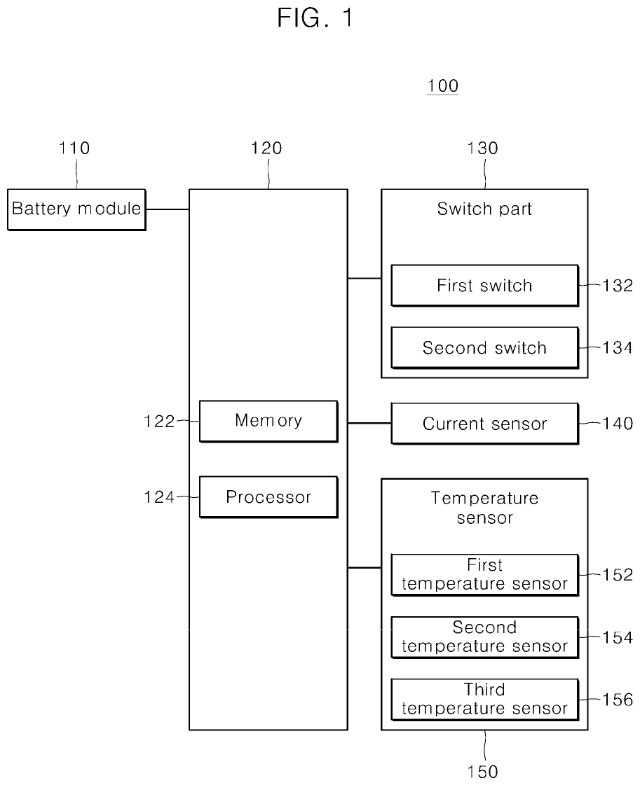

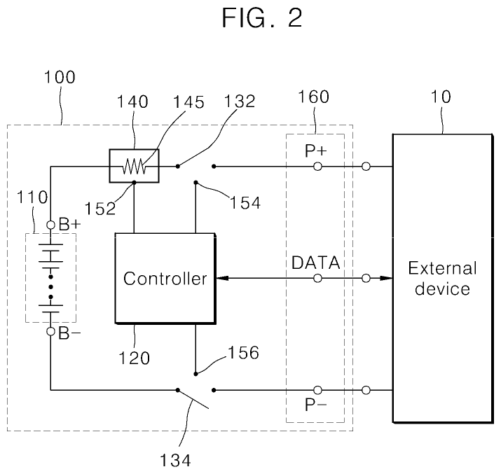

FIG. 1 is a block diagram of a battery pack and FIG. 2 is a circuit diagram of the battery pack.

Referring to FIG. 1 and FIG. 2, a battery pack 100 according to one or more embodiments of the present disclosure has a structure that can be electrically connected to an external device 10 through a cathode connection terminal P(+) and an anode connection terminal P(−). If the external device 10 is a load, the battery pack 100 is discharged by acting as a power source to provide power to the load. The external device 10 operating as a load may be, for example, an electronic device, a mobile vehicle, or an energy storage system (ESS). In one or more embodiments, the mobile vehicle may be, for example, an electric vehicle, a hybrid vehicle, or a smart mobility device.

The battery pack 100 may include at least one battery module 110, a controller 120, a switch part 130, a current sensor 140, a temperature sensor 150, and an interface 160. In various embodiments, obviously, the battery pack 100 may further include other components.

The battery module 110 may include a plurality of battery cells and a module housing. The battery module 110 may include a plurality of cells connected to each other in series or parallel. Such battery modules 110 may be connected to each other in series or parallel.

The battery cells may be stacked and received in the module housing. The battery cells may include cathode leads and anode leads. The battery cells may be round, prismatic, or pouch-type battery cells depending on the shape of the battery.

The battery pack 100 may include a single stack of cells stacked to form a single module instead of the battery modules. The cell stack may be received in an accommodation space of the pack housing, or in an accommodation space partitioned by a frame, a partition wall, or the like.

The battery cell may generate a large amount of heat during charging/discharging. The generated heat may be accumulated in the battery cell, promoting degradation of the battery cell. In one or more embodiments, the battery pack 100 may further include a cooling member to inhibit degradation of the battery cell. The cooling member may be located at a lower portion of the accommodation space which receives the battery cells. In one or more embodiments, the cooling member may be located at an upper portion or a side surface thereof depending on the battery pack 100.

Exhaust gas generated inside the battery cell due to an abnormal operating condition, also known as thermal runaway or thermal events in the battery cell, may be discharged from the battery cell. The battery pack 100 and/or the battery module 110 may include an exhaust vent or the like for discharging the exhaust gas to suppress damage to the battery pack 100 or module due to the exhaust gas.

The interface 160 may include a plurality of terminals for interfacing with the external device 10. The interface 160 may include pack terminals P+ and P− for supplying electrical energy to an external load or for receiving electrical energy from an external charging device, and a communication terminal DATA for communication with the external device 10.

The interface 160 is connected to the battery module 110, and may act as a terminal for charging the battery module 110 through connection to a charging device upon charging. The interface 160 may act as a terminal connected to an external load to discharge the battery module 110 upon discharging. To this end, the interface 160 may include a first pack terminal P+ and a second pack terminal P−. The first pack terminal P+ may be a cathode pack terminal connected to a cathode B+ of the battery module 110. The second pack terminal P− may be an anode pack terminal connected to an anode B− of the battery module 110. Charging from the charging device to the battery module 110 may occur if a charging device is connected to the interface 160, and discharging from the battery module 110 to the external load may occur if an external load is connected to the interface 160.

The switch part 130 may be controlled by a processor 124 to control electrical connection between the battery module 110 and the external device 10. The switch part 130 may include a first switch 132 connected between the cathode B+ of the battery module 110 and the first pack terminal P+, and a second switch 134 connected between the anode B− of the battery module 110 and the second pack terminal P−. The switch part 130 may be connected between the battery module 110 and at least one of the pack terminals P+ or P− to cut off, or to allow, electrical connection between the battery module 110 and the external device 10.

If the first switch 132 and the second switch 134 are turned on, power may be supplied from the battery module 110 to the external device 10, or from the external device 10 to the battery module 110. The first switch 132 and the second switch 134 may be located in a power line provided as a current path for charging and discharging the battery module 110. The first switch 132 and the second switch 134 may be implemented by any one or a combination of two or more switching devices, such as relays, transistors, and the like.

The current sensor 140 may measure a current of the battery module 110. In one or more embodiments, the current sensor 140 may be a shunt-type current sensor 140. The current sensor 140 may measure a current flow between the battery module 110 and the pack terminals P+ and/or P− to obtain the current of the battery module 110, that is, a charging current or a discharging current.

The current sensor 140 may include a shunt resistor 145. Thus, the current sensor 140 can measure the current flowing through the shunt resistor 145. The current sensor 140 including the shunt resistor 145 can calculate a current value flowing along a charge/discharge path of the battery module 110 by measuring a voltage value across the shunt resistor 145. In one or more embodiments, because resistance of the shunt resistor 145 is a known value, the current sensor 140 can calculate a current value flowing in the shunt resistor 145 if the voltage value across the shunt resistor 145 is obtained. In one or more embodiments, the calculated current value can be a current value flowing along the charge/discharge path of the battery module 110.

The shunt resistor 145 is a current-sensing resistor, and may be connected in series to a large current path to measure the current (charging current or discharging current) flowing through the large current path. The shunt resistor 145 may be connected to the large current path between the cathode B+ of the battery module 110 and the first pack terminal P+. However, the present disclosure is not limited thereto, and, according to other embodiments, the shunt resistor 145 may be connected to the large current path between the anode B− of the battery module 110 and the second pack terminal P−.

The temperature sensor 150 may measure a shunt temperature of the current sensor 140, a first switch temperature of the first switch 132, and/or a second switch temperature of the second switch 134. In one or more embodiments, the temperature sensor 150 may include a first temperature sensor 152 provided to the shunt resistor 145, a second temperature sensor 154 provided to the first switch 132, and/or a third temperature sensor 156 provided to the second switch 134. Such a temperature sensor 150 may be a thermocouple, as one example, used for temperature measurement.

The first temperature sensor 152 may measure the temperature of the shunt resistor 145, and may transmit the measured shunt temperature to the processor 124.

The second temperature sensor 154 may measure the temperature of the first switch 132, and may transmit the measured first switch temperature to the processor 124.

The third temperature sensor 156 may measure the temperature of the second switch 134, and may transmit the measured second switch temperature to the processor 124.

The controller 120 may include a memory 122 and the processor 124. The controller 120 may be included in a battery management system (BMS).

The memory 122 may store programs (applications) used by the processor 124 to diagnose the current sensor 140. In some embodiments, the memory 122 may store instructions used to operate the processor 124. In some embodiments, the memory 122 may be built into the processor 124, or may be connected to the processor 124 via a bus. In some embodiments, the memory 122 storing tables may be non-volatile memory.

The processor 124 may control on/off operations of the first switch 132 and the second switch 134 that connect the battery module 110 to the external device 10. For example, the processor 124 may turn off or on the first switch 132 and the second switch 134 to block or allow the flow of current supplied to the battery module 110 through the large current path from the external charging device. In one or more embodiments, the processor 124 may turn on the first switch 132 and the second switch 134 to allow charging or discharging of the battery module 110. In one or more embodiments, the processor 124 may turn off the first switch 132 and the second switch 134 to block the flow of current through the large current path between the battery module 110 and the external device 10.

If current flows between the battery module 110 and the external device 10, the current sensor 140 may measure the current flowing between the battery module 110 and the external device 10.

Further, the processor 124 may diagnose abnormality of the current sensor 140 based on at least one of the shunt temperature measured by the first temperature sensor 152, the first switch temperature measured by the second temperature sensor 154, or the second switch temperature measured by the third temperature sensor 156.

As the resistance value of the shunt resistor 145 increases, more energy is consumed for the same current flow. More energy consumption can indicate that more heat is likely to be generated if the resistance value of the shunt resistor 145 is large than if the resistance value of the shunt resistor 145 is small. Furthermore, if the shunt resistor 145 is in a normal condition and maintains a constant resistance value, the temperatures measured at the shunt resistor 145, the first switch 132, and the second switch 134 may be similar, because the current flowing in the first switch 132 and the second switch 134 may be substantially constant. However, if there is a problem with the shunt resistor 145, the temperatures measured at the first switch 132 and the second switch 134 might not change, whereas the temperature measured at the shunt resistor 145 can change (that is, the temperature measured at the shunt resistor 145 can become larger or smaller). Therefore, if the temperature values at the first switch 132 and the second switch 134 remain unchanged, and only the temperature value at the shunt resistor 145 changes significantly, it can be determined that the resistance value of the shunt resistor 145 has changed rather than that the current value has changed.

In one or more embodiments, the processor 124 may determine whether the shunt resistor 145 is abnormal based on the shunt temperature, the first switch temperature, and/or the second switch temperature. Because the shunt resistor 145 is included in the current sensor 140, abnormality of the shunt resistor 145 may indicate abnormality of the current sensor 140. Thus, abnormality of the shunt resistor 145 may be indicative of abnormality of the current sensor 140. Thus, the processor 124 may diagnose abnormality of the current sensor 140 based on at least one of the shunt temperature, the first switch temperature, or the second switch temperature.

Next, a method of diagnosing abnormality of the current sensor 140 by the processor 124 will be described.

The processor 124 may diagnose abnormality of the current sensor 140 by comparing at least one of the shunt temperature measured by the first temperature sensor 152, the first switch temperature measured by the second temperature sensor 154, or the second switch temperature measured by the third temperature sensor 156 with at least one of a shunt maximum temperature (e.g., a preset shunt maximum temperature), a first switch maximum temperature, or a second switch maximum temperature. In one or more embodiments, the shunt maximum temperature may be a temperature that saturates at the shunt resistor 145 at a maximum current (e.g., about 550 A), the first switch maximum temperature may be a temperature that saturates at the first switch 132 at the maximum current (e.g., 550 about A), and the second switch temperature may be a temperature that saturates at the second switch 134 at the maximum current (e.g., 550 about A).

If the current changes, the temperatures measured at the shunt resistor 145, the first switch 132, and the second switch 134 will not exceed the corresponding maximum temperatures measured at the maximum current under a constant resistance condition. In one or more embodiments, the processor 124 may use the shunt maximum temperature, the first switch maximum temperature, and the second switch maximum temperature to determine whether the current sensor 140 is abnormal.

In one or more embodiments, if the shunt temperature is less than or equal to the shunt maximum temperature, the first switch temperature is less than or equal to the first switch maximum temperature, and the second switch temperature is less than or equal to the second switch maximum temperature, the processor 124 may determine that the current sensor 140 is normal.

If the shunt temperature exceeds the shunt maximum temperature, the first switch temperature is less than or equal to the first switch maximum temperature, and the second switch temperature is less than or equal to the second switch maximum temperature, the processor 124 may determine that the current sensor 140 is abnormal. If the temperature trends of the first switch and the second switch 134 are similar, and if only the temperature trend measured at the shunt resistor 145 is different therefrom, it can be seen that there is a problem with the shunt resistor 145. In one or more embodiments, the processor 124 may determine that, if the shunt temperature exceeds the shunt maximum temperature, the first switch temperature is less than or equal to the first switch maximum temperature, and the second switch temperature is less than or equal to the second switch maximum temperature, the processor 124 may determine that the current sensor 140 is abnormal.

Upon determining that the current sensor 140 is abnormal, the processor 124 may calculate an average temperature of the shunt temperature, the first switch temperature, and the second switch temperature, and may compare the calculated average temperature with the shunt temperature, the first switch temperature, and the second switch temperature to determine the type of abnormality of the current sensor 140. In one or more embodiments, the type of abnormality of the current sensor 140 may include a shunt-resistance-value-decrease failure, a shunt-resistance-value-increase failure, and the like.

In one or more embodiments, if a difference between the shunt temperature and the average temperature is negative, a difference between the first switch temperature and the average temperature is positive, and a difference between the second switch temperature and the average temperature is positive, the processor 124 may determine that a shunt-resistance-value-decrease failure has occurred.

If the resistance value of the shunt resistor 145 decreases, a safety issue can occur because the current may be high for a desired voltage value to be measured. For example, if about 550 A or more is set as an overcurrent, the processor 124 may turn off the first switch 132 and the second switch 134 to cut off the current if the current measured through the shunt resistor 145 is about 550 A or more. However, as the resistance value of the shunt resistor decreases, the processor 124 may turn off the first switch 132 and the second switch 134 to cut off the current if the current is in the range of about 570 A to about 580 A. The processor 124 may fail to detect the overcurrent (an overcurrent detection failure), thereby causing a safety issue.

If the difference between the shunt temperature and the average temperature is positive, the difference between the first switch temperature and the average temperature is negative, and the difference between the second switch temperature and the average temperature is negative, the processor 124 may determine that a shunt-resistance-value-increase failure has occurred.

If the resistance value of the shunt resistor 145 increases, a quality issue can occur because the current may be lowered for a desired voltage value to be measured. For example, if about 550 A or more is set as an overcurrent, the processor 124 may turn off the first switch 132 and the second switch 134 to cut off the current if the current measured through the shunt resistor 145 is about 550 A or more. However, as the resistance value of the shunt resistor increases, the processor 124 may turn off the first switch 132 and the second switch 134 to cut off the current if the current is in the range of about 530 A to about 540 A. In one or more embodiments, a quality issue can occur, despite no occurrence of a safety issue.

According to one or more other embodiments of the present disclosure, the processor 124 may diagnose abnormality of the current sensor 140 based on a shunt temperature difference, which means an absolute value of a difference between the shunt temperature and a shunt saturation temperature, based on a first switch temperature difference, which means an absolute value of a difference between the first switch temperature and a first switch saturation temperature, and based on a second switch temperature difference, which means an absolute value of the difference between the second switch temperature and a second switch saturation temperature. To this end, the memory 122 may store a lookup table in which at least one of the shunt saturation temperature, the first switch saturation temperature, or the second switch saturation temperature depending upon the current is set. The shunt saturation temperature may mean a temperature saturated in the shunt resistor 145 at each current, the first switch saturation temperature may mean a temperature saturated in the first switch 132 at each current, and the second switch saturation temperature may mean a temperature saturated in the second switch at each current.

Next, a method of diagnosing abnormality of the current sensor 140 by the processor 124 using the shunt temperature difference, the first switch temperature difference, and the second switch temperature difference will be described.

The processor 124 may calculate an average value of current accumulated to date, and may obtain, from the lookup table, the shunt saturation temperature, the first switch saturation temperature, and the second switch saturation temperature corresponding to the calculated average current.

Then, the processor 124 may calculate the shunt temperature difference, which means the absolute value of the difference between the shunt temperature and the shunt saturation temperature, the first switch temperature difference, which means the absolute value of the difference between the first switch temperature and the first switch saturation temperature, and the second switch temperature difference, which means the absolute value of the difference between the second switch temperature and the second switch saturation temperature.

Then, the processor 124 may compare the shunt temperature difference, the first switch temperature difference, and the second switch temperature difference with a reference value (e.g., a preset reference value) to diagnose abnormality of the current sensor 140. In one or more embodiments, the reference value may mean twice the error rate of the temperature sensor 150. The error rate of the temperature sensor 150 may be, for example, a preset value.

In one or more embodiments, if the shunt temperature difference is less than or equal to the reference value, the first switch temperature difference is less than or equal to the reference value, and the second switch temperature difference is less than or equal to the reference value, the processor 124 may determine that the current sensor 140 is normal.

If the shunt temperature difference exceeds the reference value, the first switch temperature difference is less than or equal to the reference value, and the second switch temperature difference is less than or equal to the reference value, the processor 124 may determine that the current sensor 140 is abnormal.

Upon determining that the current sensor 140 is abnormal, the processor 124 may determine the type of abnormality of the current sensor 140 based on the sign of the difference between the shunt temperature and the shunt saturation temperature.

In one or more embodiments, if the difference between the shunt temperature and the shunt saturation temperature is negative, the processor 124 may determine that a shunt-resistance-value-decrease failure has occurred. Upon determining that the shunt-resistance-value-decrease failure occurs, a safety issue can occur.

If the difference between the shunt temperature and the shunt saturation temperature is positive, the processor 124 may determine that a shunt-resistance-value-increase failure has occurred. Upon determining that the shunt-resistance-value-increase failure occurs, a quality issue can occur, despite no occurrence of a safety issue.

Upon determining that the current sensor 140 is abnormal, the processor 124 may turn off the first switch 132 and the second switch 134 to cut off the current.

The processor 124 may be realized by a central processing unit (CPU) or system on chip (SoC), may run an operating system or application to control a plurality of hardware or software components connected to the processor 124, and may perform various data processing and computations. The processor 124 may be configured to execute at least one instruction stored in the memory 122, and to store data resulting from the execution in the memory 122.

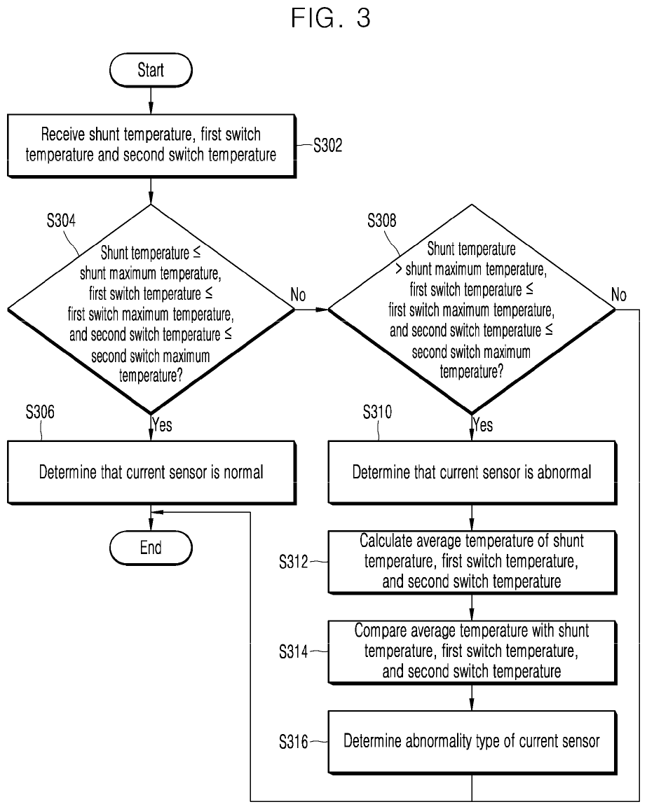

FIG. 3 is a flowchart illustrating a current sensor diagnosis method according to one or more embodiments of the present disclosure.

Referring to FIG. 3, the processor 124 receives a shunt temperature, a first switch temperature, and a second switch temperature sent from the first temperature sensor 152, the second temperature sensor 154, and the third temperature sensor 156, respectively (S302). The first temperature sensor 152 provided to the shunt resistor 145 may measure and transmit the shunt temperature to the processor 124. The second temperature sensor 154 provided to the first switch 132 may measure and transmit the first switch temperature to the processor 124. The third temperature sensor 156 provided to the second switch 134 may measure and transmit the second switch temperature to the processor 124.

After operation S302, the processor 124 determines whether the shunt temperature is less than or equal to the shunt maximum temperature, whether the first switch temperature is less than or equal to the first switch maximum temperature, and whether the second switch temperature is less than or equal to the second switch maximum temperature (S304).

Upon determining in operation S304 that the shunt temperature is less than or equal to the shunt maximum temperature, that the first switch temperature is less than or equal to the first switch maximum temperature, and that the second switch temperature is less than or equal to the second switch maximum temperature, the processor 124 determines that the current sensor 140 is normal (S306).

If it is not determined in operation S304 that the shunt temperature is less than or equal to the shunt maximum temperature, that the first switch temperature is less than or equal to the first switch maximum temperature, and that the second switch temperature is less than or equal to the second switch maximum temperature, the processor 124 determines whether the shunt temperature exceeds the shunt maximum temperature, whether the first switch temperature is less than or equal to the first switch maximum temperature, and whether the second switch temperature is less than or equal to the second switch maximum temperature (S308).

Upon determining in operation S308 that the shunt temperature exceeds the shunt maximum temperature, that the first switch temperature is less than or equal to the first switch maximum temperature, and that the second switch temperature is less than or equal to the second switch maximum temperature, the processor 124 determines that the current sensor 140 is abnormal (S310).

Upon determining that the current sensor 140 is abnormal, the processor 124 calculates an average temperature of the shunt temperature, the first switch temperature, and the second switch temperature (S312).

After operation S312, the processor 124 compares the calculated average temperature with the shunt temperature, the first switch temperature, and the second switch temperature (S314) to determine the type of abnormality of the current sensor 140 (S316). If the difference between the shunt temperature and the average temperature is negative, the difference between the first switch temperature and the average temperature is positive, and the difference between the second switch temperature and the average temperature is positive, the processor 124 may determine that a shunt-resistance-value-decrease failure has occurred. If the difference between the shunt temperature and the average temperature is positive, the difference between the first switch temperature and the average temperature is negative, and the difference between the second switch temperature and the average temperature is negative, the processor 124 may determine that a shunt-resistance-value-increase failure has occurred.

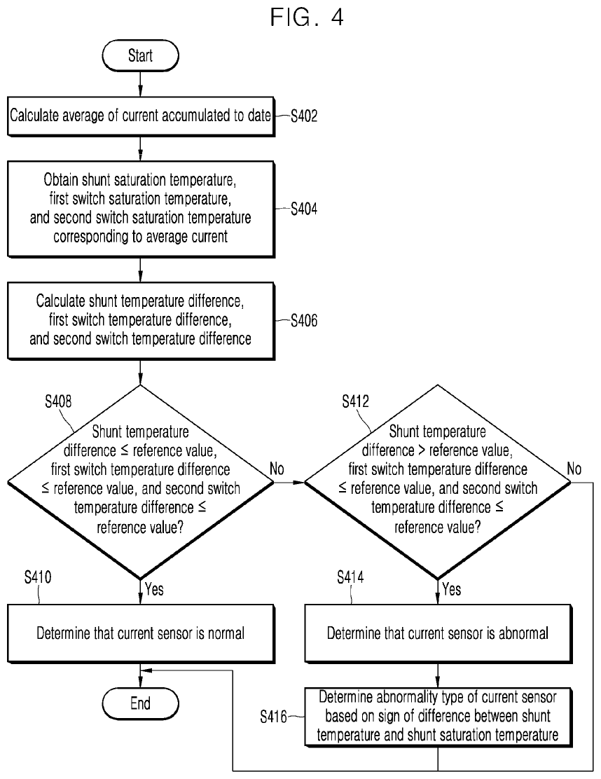

FIG. 4 is a flowchart illustrating a current sensor diagnosis method according to one or more other embodiments of the present disclosure.

Referring to FIG. 4, the processor 124 calculates an average value of the current accumulated to date (S402), and obtains, from the lookup table, a shunt saturation temperature, a first switch saturation temperature, and a second switch saturation temperature corresponding to the calculated average current (S404). Because the lookup table has the shunt saturation temperature, the first switch saturation temperature, and the second switch saturation temperature set according to the current, the processor 124 may obtain the shunt saturation current, the first switch saturation temperature, and the second switch saturation temperature corresponding to the average current from the lookup table.

After operation S404, the processor 124 calculates a shunt temperature difference, a first switch temperature difference, and a second switch temperature difference (S406). In one or more embodiments, the shunt temperature difference may mean an absolute value of a difference between the shunt temperature and the shunt saturation temperature, the first switch temperature difference may mean an absolute value of a difference between the first switch temperature and the first switch saturation temperature, and the second switch temperature difference may mean an absolute value of a difference between the second switch temperature and the second switch saturation temperature.

After operation S406, the processor 124 determines whether the shunt temperature difference is less than or equal to a reference value, whether the first switch temperature difference is less than or equal to the reference value, and whether the second switch temperature difference is less than or equal to the reference value (S408).

Upon determining in operation S408 that the shunt temperature difference is less than or equal to the reference value, the first switch temperature difference is less than or equal to the reference value, and the second switch temperature difference is less than or equal to the reference value, the processor 124 determines that the current sensor 140 is normal (S410).

If operation S408 is not satisfied, the processor 124 determines whether the shunt temperature difference exceeds the reference value, whether the first switch temperature difference is less than or equal to the reference value, and whether the second switch temperature difference is less than or equal to the reference value (S412).

Upon determining in operation S412 that the shunt temperature difference exceeds the reference value, that the first switch temperature difference is less than or equal to the reference value, and that the second switch temperature difference is less than or equal to the reference value, the processor 124 determines that the current sensor 140 is abnormal (S414).

Upon determining that the current sensor 140 is abnormal, the processor 124 determines the type of abnormality of the current sensor 140 based on the sign of the difference between the shunt temperature and the shunt saturation temperature (S416). In one or more embodiments, if the difference between the shunt temperature and the shunt saturation temperature is negative, the processor 124 may determine that a shunt-resistance-value-decrease failure has occurred. If the difference between the shunt temperature and the shunt saturation temperature is positive, the processor 124 may determine that a shunt-resistance-value-increase failure has occurred.

As described above, according to the present disclosure, the battery pack and the current sensor diagnosis method can detect abnormality (e.g., errors or failure) of the shunt resistor, thereby enabling accurate detection of overcurrent through diagnosis of abnormality of the current sensor 140 including the shunt resistor.

According to the present disclosure, the battery pack and the current sensor diagnosis method can reduce or prevent the likelihood of problems, such as battery failure and explosion due to abnormality (e.g., errors or failure) of the shunt resistor.

According to the present disclosure, the battery pack and the current sensor diagnosis method can detect abnormality (e.g., errors or failure) of a shunt resistor, and can reduce a risk caused by abnormality of the shunt resistor by changing abnormality of the shunt resistor from a single point fault to a dual point fault.

The embodiments described herein may be implemented, for example, as a method or process, a device, a software program, a data stream, or a signal. Although discussed in the context of a single type of implementation (for example, discussed only as a method), features discussed herein may also be implemented in other forms (for example, a device or a program). The device may be implemented by suitable hardware, software, firmware, and the like. The method may be implemented on a device, such as a processor that generally refers to a processing device including a computer, a microprocessor, an integrated circuit, a programmable logic device, etc. The processor includes a communication device such as a computer, a cell phone, a personal digital assistant (PDA), and other devices that facilitate communication of information between the device and end-users.

Although the present disclosure has been described with reference to some embodiments and drawings illustrating aspects thereof, the present disclosure is not limited thereto. Various modifications and variations can be made by a person skilled in the art to which the present disclosure belongs within the scope of the technical spirit of the present disclosure, and the claims and equivalents thereto.

What is claimed is:

1. A battery pack comprising:
a battery module comprising battery cells;
a current sensor for measuring a current in the battery module;
a first switch connected to a first current path between a cathode of the battery module and a first pack terminal;
a second switch connected to a second current path between an anode of the battery module and a second pack terminal;
a first temperature sensor for measuring a shunt temperature of the current sensor;
a second temperature sensor for measuring a first switch temperature of the first switch;
a third temperature sensor for measuring a second switch temperature of the second switch; and
a processor for diagnosing the current sensor based on at least one of the shunt temperature, the first switch temperature, or the second switch temperature.

2. The battery pack according to claim 1, wherein the current sensor comprises a shunt resistor, and
wherein the shunt temperature is indicative of a temperature of the shunt resistor.

3. The battery pack according to claim 1, wherein the processor is configured to diagnose an abnormality of the current sensor by comparing at least one of the shunt temperature, the first switch temperature, or the second switch temperature with at least one of a shunt maximum temperature, a first switch maximum temperature, or a second switch maximum temperature.

4. The battery pack according to claim 3, wherein the processor is configured to determine that the current sensor is normal when the shunt temperature is less than or equal to the shunt maximum temperature, the first switch temperature is less than or equal to the first switch maximum temperature, and the second switch temperature is less than or equal to the second switch maximum temperature.

5. The battery pack according to claim 3, wherein the processor is configured to determine that the current sensor is abnormal when the shunt temperature exceeds the shunt maximum temperature, the first switch temperature is less than or equal to the first switch maximum temperature, and the second switch temperature is less than or equal to the second switch maximum temperature.

6. The battery pack according to claim 5, wherein, upon determining that the current sensor is abnormal, the processor is configured to calculate an average temperature of the shunt temperature, the first switch temperature, and the second switch temperature, and is configured to compare the average temperature with the shunt temperature, the first switch temperature, and the second switch temperature to determine a type of the abnormality of the current sensor.

7. The battery pack according to claim 6, wherein the processor is configured to determine that a shunt-resistance-value-decrease failure has occurred when a difference between the shunt temperature and the average temperature is negative, a difference between the first switch temperature and the average temperature is positive, and a difference between the second switch temperature and the average temperature is positive.

8. The battery pack according to claim 6, wherein the processor is configured to determine that a shunt-resistance-value-increase failure has occurred when a difference between the shunt temperature and the average temperature is positive, a difference between the first switch temperature and the average temperature is negative, and a difference between the second switch temperature and the average temperature is negative.

9. The battery pack according to claim 1, further comprising a lookup table for setting therein at least one of a shunt saturation temperature, a first switch saturation temperature, or a second switch saturation temperature depending on current,
wherein the processor is configured to:
calculate an average of current accumulated;
obtain the shunt saturation temperature, the first switch saturation temperature, and the second switch saturation temperature corresponding to the average of the current accumulated from the lookup table;
calculate a shunt temperature difference meaning an absolute value of a difference between the shunt temperature and the shunt saturation temperature, a first switch temperature difference meaning an absolute value of a difference between the first switch temperature and the first switch saturation temperature, and a second switch temperature difference meaning an absolute value of a difference between the second switch temperature and the second switch saturation temperature; and
compare the shunt temperature difference, the first switch temperature difference, and the second switch temperature difference with a reference value to diagnose an abnormality of the current sensor.

10. The battery pack according to claim 9, wherein the processor is configured to determine that the current sensor is normal when the shunt temperature difference is less than or equal to the reference value, the first switch temperature difference is less than or equal to the reference value, and the second switch temperature difference is less than or equal to the reference value.

11. The battery pack according to claim 9, wherein the processor is configured to determine that the current sensor is abnormal when the shunt temperature difference exceeds the reference value, the first switch temperature difference is less than or equal to the reference value, and the second switch temperature difference is less than or equal to the reference value.

12. The battery pack according to claim 11, wherein, upon determining that the current sensor is abnormal, the processor is configured to determine a type of the abnormality of the current sensor based on a sign of the difference between the shunt temperature and the shunt saturation temperature.

13. The battery pack according to claim 12, wherein the processor is configured to determine that a shunt-resistance-value-decrease failure has occurred when the difference between the shunt temperature and the shunt saturation temperature is negative, and to determine that a shunt-resistance-value-increase failure has occurred when the difference between the shunt temperature and the shunt saturation temperature is positive.

14. A current sensor diagnosis method comprising:
calculating, by a processor, an average of current accumulated;
obtaining, by the processor, a shunt saturation temperature, a first switch saturation temperature, and a second switch saturation temperature corresponding to the average of the current accumulated;
calculating, by the processor, a shunt temperature difference meaning an absolute value of a difference between a shunt temperature measured by a first temperature sensor and the shunt saturation temperature, a first switch temperature difference meaning an absolute value of a difference between a first switch temperature measured by a second temperature sensor and the first switch saturation temperature, and a second switch temperature difference meaning an absolute value of a difference between a second switch temperature measured by a third temperature sensor and the second switch saturation temperature; and
diagnosing, by the processor, an abnormality of a current sensor by comparing the shunt temperature difference, the first switch temperature difference, and the second switch temperature difference with a reference value.

15. The current sensor diagnosis method according to claim 14, wherein diagnosing the abnormality of the current sensor comprises determining that the current sensor is normal when the shunt temperature difference is less than or equal to the reference value, the first switch temperature difference is less than or equal to the reference value, and the second switch temperature difference is less than or equal to the reference value.

16. The current sensor diagnosis method according to claim 14, wherein diagnosing the abnormality of the current sensor comprises determining that the current sensor is abnormal when the shunt temperature difference exceeds the reference value, the first switch temperature difference is less than or equal to the reference value, and the second switch temperature difference is less than or equal to the reference value.

17. The current sensor diagnosis method according to claim 16, further comprising determining that a shunt-resistance-value-decrease failure has occurred when the difference between the shunt temperature and the shunt saturation temperature is negative, and determining that a shunt-resistance-value-increase failure has occurred when the difference between the shunt temperature and the shunt saturation temperature is positive.

18. A current sensor diagnosis method comprising:
receiving, by a processor, at least one of a shunt temperature measured by a first temperature sensor, a first switch temperature measured by a second temperature sensor, or a second switch temperature measured by a third temperature sensor; and
diagnosing, by the processor, abnormality of a current sensor by comparing at least one of the shunt temperature, the first switch temperature, or the second switch temperature with at least one of a shunt maximum temperature, a first switch maximum temperature, or a second switch maximum temperature.

19. The current sensor diagnosis method according to claim 18, wherein diagnosing the abnormality of the current sensor comprises determining that the current sensor is normal when a shunt temperature difference, meaning an absolute value of a difference between the shunt temperature and a shunt saturation temperature, is less than or equal to a reference value, a first switch temperature difference, an absolute value of a difference between the first switch temperature and a first switch saturation temperature, is less than or equal to the reference value, and a second switch temperature difference, meaning an absolute value of a difference between the second switch temperature and a second switch saturation temperature, is less than or equal to the reference value.

20. The current sensor diagnosis method according to claim 19, wherein diagnosing the abnormality of the current sensor comprises determining that the current sensor is abnormal when the shunt temperature difference exceeds the reference value, the first switch temperature difference is less than or equal to the reference value, and the second switch temperature difference is less than or equal to the reference value.
